(19) United States
(12) Patent Application Publication
(10) Pub. No.: US 2008/0274613 A1
(43) Pub. Date: Nov. 6, 2008

(54) Method for the Protection of Openings in a Component During a Machining Process

(76) Inventors: Oliver Dernovsek, Graz (AT); Rene Jabado, Berlin (DE); Daniel Kortvelyessy, Berlin (DE); Ralph Reiche, Berlin (DE); Michael Rindler, Schoneiche (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/547,228

(22) PCT Filed: Mar. 14, 2005
(86) PCT No.: PCT/EP2005/002709

§ 371 Date: Oct. 2, 2006

(30) Foreign Application Priority Data
Apr. 2, 2004 (EP) 04008153.1

(51) Int. Cl. H01L 21/44; C04B 35/00

(52) U.S. Cl. 438/675; 501/154; 257/E21.476

(57) ABSTRACT

The invention relates to a method for the protection of openings in a component, produced from an electrically-conducting material, in particular, from metal or a metal alloy, during a machining process against the ingress of material, whereby the openings are sealed with a filler material before the machining process, which is removed again after the machining process. The machining processes particularly concern coating processes and welding processes. Said method is characterized in that an electrically-conducting filler material is applied, the electrical conductivity of which matches the electrical conductivity of the base material.

### CROSS REFERENCE TO RELATED APPLICATIONS

This application is the US National Stage of International Application No. PCT/EP2005/002709, filed Mar. 14, 2005 and claims the benefit thereof. The International Application claims the benefits of European Patent application No. 04008153.1 filed Apr. 2, 2004. All of the applications are incorporated by reference herein in their entirety.

### FIELD OF THE INVENTION

The present invention relates to a method for the protection of openings in a component, produced from an electrically conductive base material, during a machining process against the ingress of material, in which the openings are sealed with a filler material before the machining process. In addition, the invention relates to a ceramic material, in particular for use as a filler material in the method according to the invention.

### BACKGROUND OF THE INVENTION

Components that are subjected to high thermal loads, for example turbine blades of gas turbines, are often coated with a cooling film for cooling. For this purpose, these components comprise, arranged inside them, cooling fluid ducts which transport a cooling fluid which is used to build up the cooling film. In order to channel the cooling fluid, for example air, out of the interior of the component in order that it can form the cooling film, openings are present in the component, configured for example as cooling air bores. These openings make it possible for the cooling fluid to pass from the interior of a component to the outside. The cross-sectional area and the shape of the openings are in this case designed such that on the one hand the required amount of cooling fluid flows out of the component and on the other hand a suitable cooling fluid film forms on the component surface.

The described components that are subjected to high thermal loads are additionally provided with coatings, for example with an MCrAlX coating, that is to say a coating which comprises chromium (Cr), aluminum (Al), yttrium (X═Y) and a further metal (M). This coating serves for the protection of the components against oxidation and/or corrosion. Moreover, for thermal insulation, the components may be coated with a thermal insulation coating, hereafter referred to as the TBC layer (Thermal Barrier Coating) for short.

The operation of the components leads to the coating or the coatings becoming worn, to be precise often already before the structural integrity of the component is reduced to the extent that it can no longer continue to be operated. The components are therefore newly coated, in order to pass them on for further use. However, even when the component is merely to be tested, for example for structural defects, new coating may become necessary, that is whenever all the coatings have to be removed for the testing of the component. During recoating, there is the problem that cooling air bores may become sealed by the coating material, for example MCrAlX, or reduced in their diameter. The reduction of the diameter thereby reduces the outlet area of the opening, whereby the cooling effect by the cooling film changes and is possibly reduced. Moreover, if the outlet area of the opening becomes too small, the flow required for the cooling effect, which is for example laminar or turbulent, can no longer be ensured. In both cases, this leads to premature failure of the component on account of overheating. The reduction of the diameter of the openings is also known as the “down-coat effect”.

One possibility for counteracting the down-coat effect is that the coating on the inner side of the opening leading to reduction of the opening diameter after recoating is removed manually, for example by means of a diamond file, or with a laser. Sometimes, quartz pins are also inserted in cooling air bores during the coating operation and subsequently have to be washed out by means of an acid or an alkaline solution. Furthermore, also described in the literature is the reopening of cooling air bores by means of EDM or flow grinding.

Furthermore, methods are described in which cooling air bores of gas turbine components are sealed before coating by means of a masking material, which is filled into the cooling air bores. The material is subsequently left to cure. The coating process is carried out with the cooling air bores protected in this way. The masking material is subsequently removed.

U.S. Pat. No. 5,902,647 and EP 1 076 106 describe for example methods in which the masking material is filled into the holes in such a way that it protrudes beyond the outer surface of the turbine component. In this case, however, it is difficult to ensure that the masking material does not extend laterally beyond the edge of the hole, so that the coating also actually reaches the edge of the hole after recoating.

U.S. Pat. No. 4,726,104 describes a method in which a masking is introduced into cooling air bores.

U.S. Pat. No. 3,099,578 discloses an electrically conducting composition of carbon and silver, which are mixed with each other in a resin.

JP 2003342707 discloses a method for coating an outer surface, holes being present in the outer surface and said holes being filled with a mixture of a metallic material and a resin.

JP 2003306760 likewise discloses a method for masking holes which are protected by a metal rod coated with carbon.

WO 03/089679 describes a method in which the masking material is filled into the cooling air bores of a turbine blade in such a way that its surface finishes flush with the surface of the turbine component. By suitable choice of the masking material and filler materials in the masking material, it is thereby ensured that the coating material does not adhere on the masking material.

A two-stage method is used here for sealing the cooling air bore. Firstly, a deformable composition is introduced, which then has to be cured in a second step.

Furthermore, the polymers which are part of the filler material form soot streaks on the component during burning off.

### SUMMARY OF THE INVENTION

The object of the present invention is to provide a method that is improved in comparison with the prior art for the protection of openings in a component against the ingress of coating material during a machining process.

A further object of the present invention is to provide a ceramic material which has advantageous properties and is suitable in particular for use in the method according to the invention.

The first object is achieved by a method as claimed in the claims, the second object by a ceramic material as claimed in the claims.

The dependent claims contain advantageous refinements of the method or of the ceramic material and can be combined with one another in an advantageous way.

In the method according to the invention for the protection of openings in a component produced from an electrically conductive base material, in particular from metal or metal alloy, during a machining process against the ingress of material, the openings are sealed before the machining process with a filler material, which is removed again after the machining process. Machining processes that may be concerned here are, in particular, coating processes and soldering processes. The method according to the invention is distinguished by the fact that an electrically conductive filler material, the electrical conductivity of which is adapted in particular to the electrical conductivity of the base material, i.e. comes as close as possible to the electrical conductivity of the base material, is used as the filler material. It is particularly advantageous if a filler material of a conductivity that corresponds to that of the base material is used as the filler material.

The advantage of the method according to the invention over the previous methods is that the machining process is impaired less by the filler material. For example, during an MCrAlX coating process, what is known as cleaning sputtering occurs, with the component being exposed to an arc. On account of the conductivity of the filler material that is adapted to the base material, the arc is not significantly impaired at the transitions between the surface of the base material and the surface of the filler material. Impairment could lead to damage in the component. Many coating processes, for instance coating processes with MCrAlX, also comprise at least one heating process. On account of the conductivity of the filler material that is adapted to the base material, the heat introduced into the component at the transitions between the base material and the filler material is not disturbed.

A curable filler material, in particular a ceramic filler material, is preferably used as the filler material, in order to increase the strength or the stability of the filler material that is filled into the openings during the machining process. The curing takes place after the openings have been filled with the filler material. If the curable filler material is a ceramic filler material, a coating material to be applied in the course of a coating process will not adhere to the filler material, or only to a limited extent, on account of the ceramic properties of the filler material. This applies especially to MCrAlX coatings.

The curing of the filler material can be achieved by a suitable heat treatment. In an advantageous way, the heat treatment may be realized by a heat treatment carried out in the course of the machining process or be integrated in such a heat treatment, so that an additional heat treatment step is not necessary.

The curable filler material may be introduced into at least some of the openings in particular as a paste. The introduction of the paste, which may take place for example by means of a spatula device, offers the advantage that holes shaped in any way desired can be filled in this way.

As an alternative or in addition, however, it is also possible to introduce into at least some of the openings preformed, at least partially crosslinked filling bodies or filling bodies which no longer have to be heat-treated and for example adhere mechanically in the cooling air bores.

Partially crosslinked filling bodies are filling bodies which comprise a polymer-based binder which has a partially crosslinked polymer architecture. A partially crosslinked state is also referred to as a “green state” and offers greater dimensional stability than a paste, so that the material can maintain a physical shape already before curing. The filling of openings by means of such partially crosslinked filling bodies is suitable in particular for introducing the filler material into large openings, as are encountered for example in the region of the blade base of turbine blades. Furthermore, curved component surfaces can be protected over their entire surface area by means of partially crosslinked filling bodies, for example if the partially crosslinked filling bodies are in the form of tapes or sheets.

The material properties of the curable filler material and/or the curing conditions may be chosen in such a way that the filler material only partially cures. If the material properties and/or the curing conditions are chosen such that the filler material cures only in the region of the contact zones with the base material of the component, but is only partially crosslinked or remains partially crosslinked in the volume of the filler material, the removal of the filler material after the machining process can be performed by means of a suitable blasting method, in particular by means of a CO₂ blasting method. In a blasting method, a suitable material, for example CO₂ (carbon dioxide) in the form of dry ice, is blasted onto the component under pressure, in order to remove the filler material from the openings. The removal of the filler material by means of dry ice blasting does not impair an MCrAlX coating for instance. Furthermore, “washing out” of the beta phase of an MCrAlX coating is entirely ruled out when the filler material is removed by means of dry ice blasting.

A ceramic material according to the invention which may be used in particular as the filler material in the method according to the invention comprises at least one binder and a filler, the binder and/or the filler comprising at least one electrically conductive component. In particular, the binder and/or the filler may comprise carbon as the electrically conductive component.

Alternatively, it is also possible that the filler comprises a metal powder as the electrically conductive component, which establishes the electrical conductivity.

In the ceramic material according to the invention, the conductivity of the cured material can be specifically set by suitable composition of the binder and the filler, in particular by suitable choice of the electrically conductive component. For instance, the material offers the possibility of adapting its conductivity to the conductivity of the base material of that component into the openings of which it is to be filled. The ceramic properties of the material in this case ensure that possible coatings adhere poorly on the surface of the curable material, making it suitable in particular for use in the method according to the invention.

The ceramic material according to the invention may in particular comprise a carbon precursor as the binder. In this case, the carbon of the carbon precursor can establish the conductivity after curing. No metal powder need then be added to the filler.

The ceramic material may comprise a solvent for preparing a dispersion of the binder and the filler. Use of the solvent makes it possible to make a ceramic material capable of flowing before curing and in this way allow the material to be brushed or injected into openings. Solvents that may be concerned here are, for example, alcohol or terpineol.

In an advantageous development of the ceramic material, the filler comprises particles of at least two particle sizes, the particle sizes lying in particular in the nanometer range (in particular smaller than 0.1 μm) and/or micrometer range. Using particles of different sizes allows the proportion of filler in the ceramic material to be increased.

### BRIEF DESCRIPTION OF THE DRAWINGS

Further features, properties and advantages of the present invention emerge from the following description of an exemplary embodiment with reference to the accompanying drawings.

FIG. 1 shows a detail of a turbine blade with cooling air bores in a schematic representation,

FIG. 2 shows a first example of the introduction of the curable material according to the invention into the cooling air bores of turbine blades,

FIG. 3 shows a second example of the introduction of the curable material according to the invention into the cooling air bores of turbine blades,

FIG. 4 shows a turbine blade,

FIG. 5 shows a combustion chamber and

FIG. 6 shows a turbine.

### DETAILED DESCRIPTION OF THE INVENTION

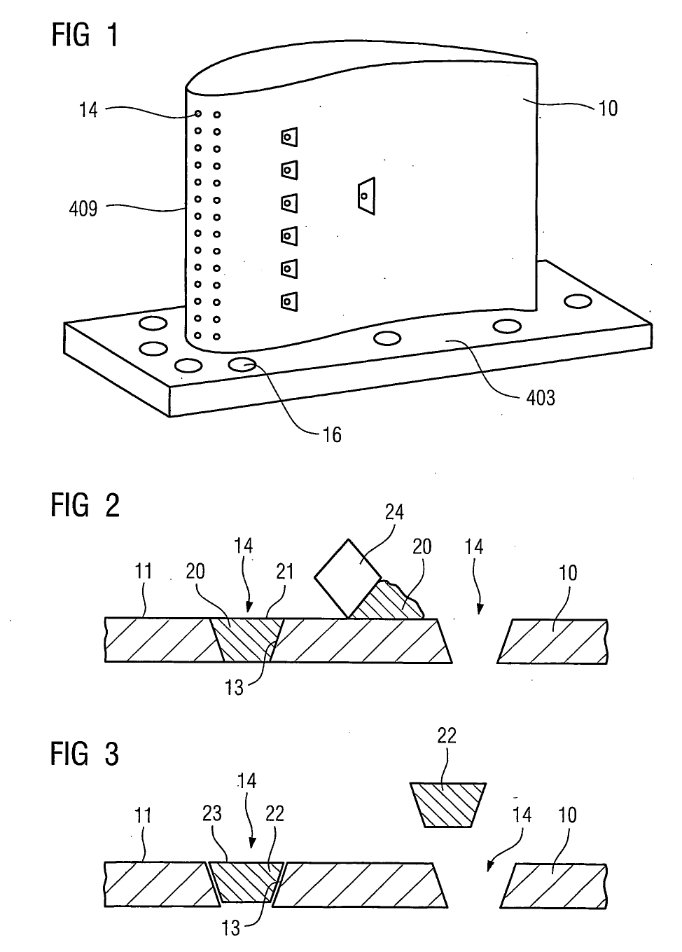

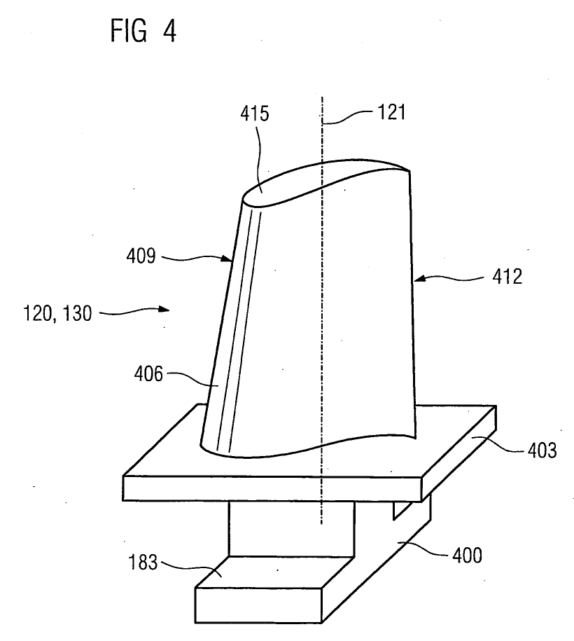

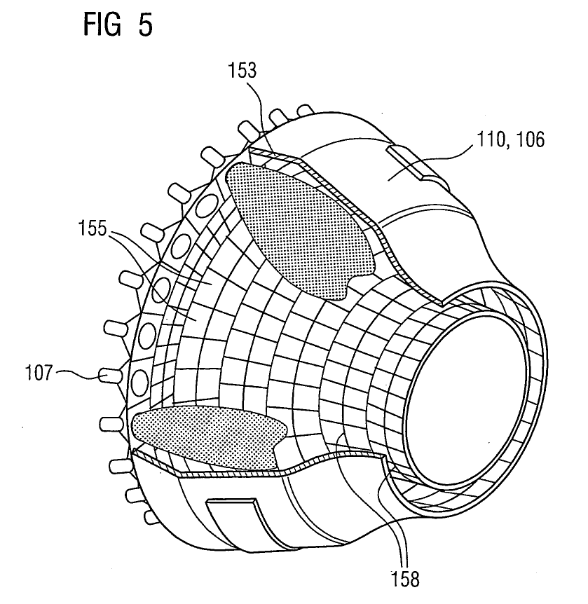

FIG. 1 shows a detail of a turbine blade 10, 120, 130 (FIGS. 4, 5) in a schematic representation. The following explanations also apply to other components which have holes, such as heat shielding elements 155 (FIG. 5) for example.

The turbine blade 10 is connected to a base plate 403 and has a number of cooling air openings 14, only some of which, located in the region of the front edge 409 of the turbine blade 10, are represented here.

In the same way as the turbine blade 10, the base plate 403 also has cooling air openings 16, the diameter of which in the present example is larger than the diameter of the cooling air openings 14 in the turbine blade 10 itself.

The cooling fluid, generally cooling air, is fed to the cooling air openings 14 of the turbine blade through cooling air ducts (not represented), which are arranged in the interior of the turbine blade 10.

The turbine blade 10 and the base plate 403 are provided with a coating, in order to protect it against oxidation and/or corrosion. The coating concerned may be an MCrAlX coating for example. Over this coating, a further coating may be present as a thermal barrier (TBC coating) for thermal insulation.

If these coatings become worn or in the case of certain maintenance work, the coatings are removed from the turbine blade. A new coating is subsequently applied.

Before the application of the new coating, the cooling air openings 14 and 16 are sealed with a filler material 20, 22, in order to prevent the openings 14, 16 from filling during the coating with coating material and in this way reducing the effective flow cross-sectional area of the openings.

The filler material 20, 22 with which the openings are sealed is a curable material which in the cured state has a conductivity which corresponds substantially to that of the base material of the turbine blade 10. The composition of the curable material is described below.

In the present exemplary embodiment, the curable material is a ceramic material which comprises at least one binder and at least one filler. The binder and/or the filler in this case comprises or comprise at least one electrically conductive component. There may possibly also be a number of electrically conductive components present. The electrically conductive components concerned may in this case be carbon and/or metal powder. Inorganic and/or organic binders or organosilicon binders, for example siloxanes or silicones, may be used as binders.

Possible compositions of the ceramic material are represented in Table 1.

| C1 paste | C2 paste | Me | Crosslinking |
|---|---|---|---|
| % by volume | % by volume | % by volume | T, ° C. |
| 100 | 0 | 0 | about 220° C. |
| 0 | 100 | 0 | about 220° C. |
| 50 | 50 | 0 | about 220° C. |
| 40 | 40 | 20 | about 220° C. |
| 80 | 0 | 20 | about 220° C. |

C1: for example graphite as the electrically conductive material (particle diameter: about 1 μm, mixture of graphite/binder in % by volume: 65 graphite/35 binder)

C2: for example graphite as the electrically conductive material (particle diameter: about 11 μm, mixture of graphite/binder in % by volume: 65 graphite/35 binder) Me: metal or metal alloy of the base material (particle diameter: about 25 μm)

Further possible compositions of the ceramic material are represented in Table 2.

| C3 paste | C4 paste | Me | Crosslinking |
|---|---|---|---|
| % by volume | % by volume | % by volume | T, ° C. |
| 100 | 0 | 0 | about 180° C. |
| 0 | 100 | 0 | about 190° C. |
| 50 | 50 | 0 | about 180° C. |
| 35 | 45 | 20 | about 190° C. |
| 80 | 0 | 20 | about 185° C. |

C3: for example graphite as the electrically conductive material (particle diameter: about 0.1 μm, mixture of graphite/binder in % by volume: 65 graphite/35 binder)

C4: for example graphite as the electrically conductive material (particle diameter: about 5.5 μm, mixture of graphite/binder in % by volume: 65 graphite/35 binder)

Me: metal or metal alloy of the base material (particle diameter: about 15 μm)

Apart from the binder, the ceramic material may also comprise a solvent, for example an alcohol- or terpineol-based solvent, in order to produce a flowable dispersion of the binder and the filler material. The viscosity of the dispersion can be influenced by the type and amount of solvent. For example, a higher proportion of solvent increases the viscosity of the dispersion.

The carbon and/or the metal powder may in particular have particles with different diameters in the nanometer and/or micrometer range (less than 500 μm). Preferably at least two particle sizes are present, for example the carbon having a different particle size than the metal powder. However, it is also possible that the carbon is already in two particle sizes or the metal powder is already in two particle sizes. Examples of materials in which two or more particle sizes are present can likewise be taken from Table 1 or 2.

The particle diameters are in this case of significance for the compacting behavior of the material, the pore distribution of the material after crosslinking and the reactivity of the material with the gas phase. With a higher number of different particle diameters, for example, a higher compaction of the material can be achieved than with merely a single particle diameter.

The coefficient of thermal expansion of the ceramic material can be varied by the type of filler, in particular by the proportion of metal powder in the filler. However, too high a proportion of metal can lead to excessive adhesion of the ceramic material to the base material of the turbine blade, so that removal of the ceramic material after coating is made more difficult. Apart from being influenced by the metal fraction, the adhesion of the ceramic material to the substrate is also influenced by the temperature prevailing during the heat treatment for curing the ceramic material. A higher temperature in this case leads to stronger adhesion of the ceramic material, in particular the metal fractions of the ceramic material, to the base material. The compacting behavior of the ceramic material also depends on the temperature prevailing during curing. Finally, the proportion of carbon and/or metal in the filler material influences the electrical conductivity of the ceramic material, and consequently also its thermal conductivity. The proportion of carbon and/or metal in the filler is generally chosen such that the electrical conductivity and/or the coefficient of thermal expansion of the ceramic material does not or do not deviate too much from the corresponding values of the base material of the turbine blade. This can be achieved for example by the metal or the metal alloy of the base material being chosen as a metal component of the filler. As already mentioned further above, it must be ensured when choosing the amount of metal powder to be added that excessively intimate bonding of the ceramic material with the base material does not occur during curing, since this would make removal of the filler after the coating process more difficult.

The introduction of the ceramic material into the openings 14 in the turbine blade 10 is represented in FIGS. 2 and 3.

In the method represented in FIG. 2 for introducing the ceramic material 20, the ceramic material 20 is in the form of a paste. The composition is brushed into the openings 14 by means of a spatula-like device 24, so that, after it has been brushed into the openings, the surface 21 of the ceramic material 20 finishes flush with the surface 11 of the turbine blade 10, i.e. does not protrude beyond the surface 11 of the turbine blade. Instead of brushing the paste into the openings, injection of the paste is also possible.

An alternative for introducing the ceramic material is represented in FIG. 3.

This alternative is suitable in particular for introducing the ceramic material into openings 16 with a relatively large diameter, as may be found for instance in the base plate 12. According to the second variant, the ceramic material is inserted into the openings in the partially crosslinked state, known as the green state, as a molding.

Similarly, a molding that cannot be cured any more may be used.

A molding may in this case take the form of a pin, knob, peg, etc. It is inserted in such a way that its surface 23 finishes flush with the surface 11 of the turbine blade 10. In particular, it is possible to adapt the molding to the cross section of the opening to be filled.

The molding may, for example, be punched out from a sheet which consists of the ceramic material in the green state. Sheets or tapes of the ceramic material in the green state may also be used to protect flat portions of the turbine blade during the coating operation.

If the ceramic material is brushed or injected into the openings as a paste, crosslinking of the polymer constituents, that is for example of the inorganic and/or organic binder or of the organosilicon binder, is subsequently performed by means of a heating step, which takes place at temperatures of approximately 200° C., in order to produce provisional dimensional stability of the ceramic material before carrying out the coating process.

If, as represented in FIG. 3, the ceramic material is used as a green molding, a crosslinking or at least a partial crosslinking of the ceramic material must be performed beforehand, in order to ensure the dimensional stability of the molding already before insertion into the openings. The crosslinking or partial crosslinking is in this case performed by a suitable heat treatment with temperatures of no more than about 200° C., at which the inorganic and/or organic binder or the organosilicon binder assumes an at least partially crosslinked polymer architecture.

This is followed by a pyrolytic conversion (firing or ceramizing) of the material introduced into the openings at temperatures above about 400 to 450° C., in order to bring about the ceramizing of the material. This firing operation may be integrated in the coating process. For example, the coating process for applying an MCrAlX coating comprises a preheating operation, in which the said temperatures are reached or exceeded.

During the firing, the ceramic material is compacted. Furthermore, pores are formed in the material with open or closed porosity.

The compacting behavior and the pore distribution in the cured material in this case depend on the one hand on the choice of binder, for example on the carbon concentration of the binder, and on the other hand on the particle diameters of the filler. It should be ensured when choosing the binder and suitable particle diameters of the filler that the resultant pores ensure adequate stability of the cured material and are not so large that the coating material reaches the walls of the openings through the pores.

Depending on the type of binder used and the type of ceramic to be produced, the firing operation takes place either with the exclusion of air, for example in an inert gas atmosphere, or in an atmosphere of air.

If a binder based on carbon is used on the basis of an organic binder, the firing operation takes place with the exclusion of air, in order that the carbon is not oxidized to form CO or CO₂. In the case of the combustion process under inert gas, up to 90% of the carbon remains in the material. If the filler comprises metal powder, metal-carbidic phases are thereby produced. Some metal carbides, for example aluminum carbide, offer the possibility of flushing the cured ceramic material out of the openings by means of water after completion of the coating process, since they react with water and are soluble.

Metals which do not form carbides at the coating or machining temperatures may also be selected.

If organosilicon binders, such as siloxanes or silicones, are used, silicon-carbidic phases may be produced during the firing (when firing with the exclusion of air) or silicon-oxidic phases may be produced (when firing in air). It is possible here by means of the composition of the atmosphere under which the firing operation takes place and the composition of the organosilicon binder to set how high the proportion of oxidic phases is in relation to the carbidic phases after the firing operation.

During the firing, it is possible to set the proportion of silicon oxide in the ceramic material after the firing operation infinitely variably in the range between 0% and 100% silicon oxide. In this case, 0% silicon oxide can be realized for example by using inorganic and/or organic binders.

The composition of the binder, the composition of the filler material and the temperature and duration of the firing operation can be chosen for the ceramic material according to the invention in such a way that it completely cures only in the region of its surface or its contact area 13 with the metal. In the interior of its volume, the ceramic material is then in a non-cured, crosslinked or partially crosslinked state. As a result, the removal of the ceramic material after the coating operation by means of a blasting process is made easier.

If its composition and the curing conditions have been suitably chosen, the removal of the ceramic material from the openings can be performed by means of dry ice blasting. Removal by means of dry ice blasting does not impair metallic MCrAlX coatings for example. Furthermore, “washing out” of the beta phase of the MCrAlX coating is entirely ruled out.

The ceramic material according to the invention may possibly additionally comprise additives in traces, i.e. with a volume fraction of less than 1%. The additives concerned may be, for instance, catalysts which promote crosslinking of the binder at temperatures below about 200° C. Platinum may be used for example as such a catalyst. Additives for influencing the surface tension of the solvent, and consequently for specific substrate adhesion, are also conceivable.

In the exemplary embodiment, the method according to the invention is described for the protection of openings in a component produced from a base material on a metal basis against the ingress of coating material during recoating of the component. However, the method may also be advantageously used in the case of first-time coating, if openings to be protected are already present in the component before the first-time coating.

A further application area of the ceramic material according to the invention is offered in the case of soldering processes. For instance, what are known as “stop-offs” are used in the soldering of turbine blades, in order to protect cooling air bores against the ingress of solder. Instead of the “stop-offs”, the ceramic material according to the invention may be used in an advantageous way for the protection of the cooling air bores. After the soldering, the ceramic material does not have to be removed from the openings and can remain in the openings for a subsequent coating process. This means that process steps can be saved and throughput times can be lowered.

FIG. 4 shows a blade 120, 130, which extends along a longitudinal axis 121, in a perspective view.

The blade 120 may be a moving blade 120 or a stationary blade 130 of a turbomachine. The turbomachine may be a gas turbine of an aircraft or a power plant for generating electricity, a steam turbine or a compressor.

The blade 120, 130 has, following one after the other along the longitudinal axis 121, a fastening region 400, an adjoining blade platform 403 and a blade airfoil 406. As a stationary blade 130, the blade 130 may have a further platform at its blade tip 415 (not represented).

In the fastening region 400 there is formed a blade root 183, which serves for the fastening of the blades 120, 130 to a shaft or a disk (not represented). The blade root 183 is designed for example as a hammer head. Other designs as a firtree or dovetail root are possible.

The blade 120, 130 has for a medium which flows past the blade airfoil 406 a leading edge 409 and a trailing edge 412.

In the case of conventional blades 120, 130, solid metallic materials are used for example in all the regions 400, 403, 406 of the blade 120, 130.

The blade 120, 130 may in this case be produced by a casting method, also by means of directional solidification, by a forging method, by a milling method or combinations of these.

Workpieces with a monocrystalline structure or structures are used as components for machines which are exposed to high mechanical, thermal and/or chemical loads during operation.

The production of monocrystalline workpieces of this type takes place for example by directional solidification from the melt. This involves casting methods in which the liquid metallic alloy directionally solidifies to form the monocrystalline structure, i.e. to form the monocrystalline workpiece. Dendritic crystals are thereby oriented along the thermal flow and form either a columnar grain structure (i.e. grains which extend over the entire length of the workpiece and are commonly referred to here as directionally solidified) or a monocrystalline structure, i.e. the entire workpiece comprises a single crystal. In these methods, the transition to globulitic (polycrystalline) solidification must be avoided, since undirected growth necessarily causes the formation of transversal and longitudinal grain boundaries, which nullify the good properties of the directionally solidified or monocrystalline component.

While reference is being made generally to solidified structures, this is intended to mean both monocrystals, which have no grain boundaries or at most small-angle grain boundaries, and columnar crystal structures, which indeed have grain boundaries extending in the longitudinal direction but no transversal grain boundaries. These second-mentioned crystalline structures are also referred to as directionally solidified structures.

Such methods are known from U.S. Pat. No. 6,024,792 and EP 0 892 090 A1.

Refurbishment means that components 120, 130 may have to be freed of protective layers after use (for example by sandblasting). This is followed by removal of the corrosion and/or oxidation layers or products. If applicable, cracks in the component 120, 130 are then also repaired. This is followed by recoating of the component 120, 130 and renewed use of the component 120, 130.

The blade 120, 130 may be hollow or be of a solid form. If the blade 120, 130 is to be cooled, it is hollow and may also have film cooling holes (not represented). As protection against corrosion, the blade 120, 130 has for example corresponding coatings, usually metallic coatings, and, as protection against heat, usually also a ceramic coating.

FIG. 5 shows a combustion chamber 110 of a gas turbine. The combustion chamber 110 is designed for example as what is known as an annular combustion chamber, in which a multiplicity of burners 107, which are arranged around the turbine shaft 103 in the circumferential direction, open out into a common combustion chamber space. For this purpose, the combustion chamber 110 is designed as a whole as an annular structure, which is positioned around the turbine shaft 103.

To achieve a comparatively high efficiency, the combustion chamber 110 is designed for a comparatively high temperature of the working medium M of approximately 1000° C. to 1600° C. To permit a comparatively long operating time even with these operating parameters that are unfavorable for the materials, the combustion chamber wall 153 is provided on its side facing the working medium M with an inner lining formed by heat shielding elements 155. Each heat shielding element 155 is provided on the working medium side with a particularly heat-resistant protective layer or is produced from material that is resistant to high temperature. On account of the high temperatures in the interior of the combustion chamber 110, a cooling system is also provided for the heat shielding elements 155 or for their holding elements.

The materials of the combustion chamber wall and their coatings may be similar to the turbine blades.

The combustion chamber 110 is designed in particular for detection of losses of the heat shielding elements 155. For this purpose, a number of temperature sensors 158 are positioned between the combustion chamber wall 153 and the heat shielding elements 155.

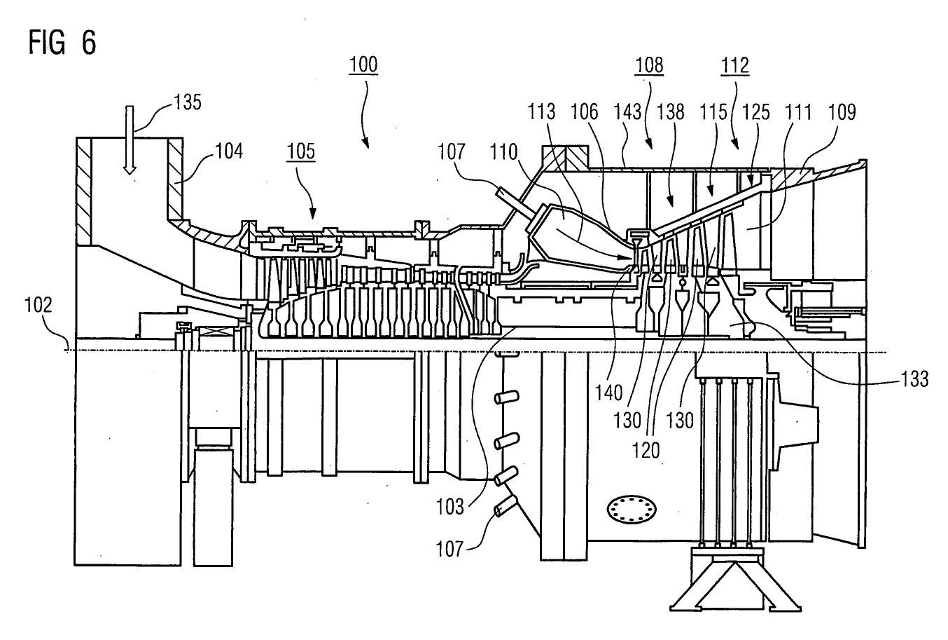

FIG. 6 shows by way of example a gas turbine 100 in a longitudinal partial section.

The gas turbine 100 has in the interior a rotor 103, which is rotatably mounted about an axis of rotation 102 and is also referred to as a turbine runner.

Following one another along the rotor 103 are an intake housing 104, a compressor 105, a combustion chamber 110, for example of a toroidal form, in particular an annular combustion chamber 106, with a number of coaxially arranged burners 107, a turbine 108 and the exhaust housing 109.

The annular combustion chamber 106 communicates with a hot gas duct 111, for example of an annular form. There, the turbine 108 is formed for example by four successive turbine stages 112.

Each turbine stage 112 is formed for example by two blade rings. As seen in the direction of flow of a working medium 113, a row of stationary blades 115 is followed in the hot gas duct 111 by a row 125 formed by moving blades 120.

The stationary blades 130 are in this case fastened to an inner housing 138 of a stator 143, whereas the moving blades 120 of a row 125 are attached to the rotor 103, for example by means of a turbine disk 133.

Coupled to the rotor 103 is a generator or a machine (not represented).

During the operation of the gas turbine 100, air 135 is sucked in by the compressor 105 through the intake housing 104 and compressed. The compressed air provided at the end of the compressor 105 on the turbine side is passed to the burners 107 and mixed there with a fuel. The mixture is then burned in the combustion chamber 110 to form the working medium 113. From there, the working medium 113 flows along the hot gas duct 111, past the stationary blades 130 and the moving blades 120. At the moving blades 120, the working medium 113 expands, transferring momentum, so that the moving blades 120 drive the rotor 103 and the latter drives the machine coupled to it.

The components that are exposed to the hot working medium 113 are subjected to thermal loads during the operation of the gas turbine 100. The stationary blades 130 and moving blades 120 of the first turbine stage 112, as seen in the direction of flow of the working medium 113, are thermally loaded the most, along with the heat shielding bricks lining the annular combustion chamber 106.

In order to withstand the temperatures prevailing there, these may be cooled by means of a coolant.

Similarly, substrates of the components may have a directed structure, i.e. they are monocrystalline (SX structure), or have only longitudinally directed grains (DS structure).

Iron-, nickel- or cobalt-based superalloys are used for example as the material for the components, in particular for the turbine blade 120, 130 and components of the combustion chamber 110.

Such superalloys are known for example from EP 1204776, EP 1306454, EP 1319729, WO 99/67435 or WO 00/44949; these documents constitute part of the disclosure.

Similarly, the blades 120, 130 may have coatings against corrosion (MCrAlX; M is at least one element of the group comprising iron (Fe), cobalt (Co) and nickel (Ni), X is an active element and represents yttrium (Y) and/or silicon and/or at least one element of the rare earths) and heat by a heat insulating layer.

The heat insulating layer consists for example of ZrO₂, Y₂O₄—ZrO₂, i.e. it is not stabilized or is partly or completely stabilized by yttrium oxide and/or calcium oxide and/or magnesium oxide.

Columnar grains are produced in the heat insulating layer by suitable coating methods, such as for example electron-beam physical vapor deposition (EB-PVD).

The stationary blade 130 has a stationary blade root facing the inner housing 138 of the turbine 108 (not represented here) and a stationary blade head, lying opposite the stationary blade root. The stationary blade head is facing the rotor 103 and fixed to a fastening ring 140 of the stator 143.

1-24. (canceled)

25. A method of protecting openings in an electrically conductive component against the ingress of material during a machining process, comprising:
filling the openings of the component with an electrically conductive filler material prior to the machining process where the filler material comprises an electrically conductive binder and an electrically conductive filler and the electrical conductivity of the filler material is similar to the electrical conductivity of the base material;
machining the component; and
removing the filler material to expose the openings,
wherein the binder or the filler comprises carbon or a carbon precursor as the electrically conductive component.

26. The method as claimed in claim 25, wherein the binder and the filler comprise carbon or a carbon precursor as the electrically conductive component.

27. The method as claimed in claim 25, wherein the filler material conductivity is the same as the component base material.

28. The method as claimed in claim 25, wherein the filler material is curable and the curing step occurs after the openings have been filled with the filler material.

29. The method as claimed in claim 28, wherein a ceramic filler material is used as the curable filler material.

30. The method as claimed in claim 28, wherein the curing is occurs during a heat treatment of a coating process.

31. The method as claimed in claim 28, wherein the filler material introduced into a portion of the openings as a paste.

32. The method as claimed in claim 28, wherein the filler material introduced into a portion of the openings is a partially crosslinked filling body.

33. The method as claimed in claim 28, wherein the material properties of the filler material or the curing conditions are determined such that the filler material only partially cures.

34. The method as claimed in claim 33, wherein the material properties of the filler material or the curing conditions are determined such that complete curing of the filler material only takes place in a region of the filler material where the filler material contacts the component base material.

35. The method as claimed in claim 25, wherein the filler material is removed by a blasting method.

36. The method as claimed in claim 35, wherein the blasting method is a CO₂ blasting or a dry ice blasting.

37. The method as claimed in 25, wherein the machining process is selected from the group consisting of: a coating process, a soldering process and a sputtering process.

38. A ceramic filler material for use as a protective machining filler material, comprising:
an organosilicon binder material; and
an electrically conductive filler material having a carbon or metal powder as an electrically conductive agent,
wherein the carbon or the metal powder comprises particles of a plurality of particle sizes.

39. The ceramic material as claimed in claim 38, wherein carbon powder is the electrically conductive agent in the filler material.

40. The ceramic material as claimed in claim 38, wherein the filler comprises an electrically conductive component selected from the group consisting of: a metal powder, carbon powder and a carbon precursor.

41. The ceramic material as claimed in claim 40, further comprising a terpineol-based solvent material for preparing a dispersion of the binder and the electrically conductive components.
